(19) United States
(12) Patent Application Publication
(10) Pub. No.: US 2024/0224649 A1
(43) Pub. Date: Jul. 4, 2024

(54) DISPLAY APPARATUS

(71) Applicant: Samsung Display Co., Ltd., Yongin-si (KR)

(72) Inventors: Seongwon Kim, Yongin-si (KR); Dongchul Shin, Yongin-si (KR); Jiwon Lee, Yongin-si (KR)

(21) Appl. No.: 18/396,379

(22) Filed: Dec. 26, 2023

(30) Foreign Application Priority Data
Dec. 30, 2022 (KR) 10-2022-0191041

(51) Int. Cl. H10K 59/131; H10K 59/80

(52) U.S. Cl. CPC H10K 59/131; H10K 59/873; H10K 2102/311

(57) ABSTRACT

A display apparatus is provided, the display apparatus including a substrate including a first pixel area and a second pixel area spaced from each other, and a first connection area between the first pixel area and the second pixel area, a 1-1st electrode in the first pixel area, a 1-2nd electrode in the second pixel area, a second electrode above the 1-1st electrode and the 1-2nd electrode, and extending in the first pixel area, the second pixel area, and the first connection area, a pattern layer above the second electrode in the first connection area, and biased from a center portion of the first connection area toward the first pixel area or the second pixel area, in plan view, and an encapsulation layer covering the pattern layer, and extending in the first pixel area, the second pixel area, and the first connection area.

### CROSS-REFERENCE TO RELATED APPLICATION

This application claims priority to, and the benefit of, Korean Patent Application No. 10-2022-0191041, filed on Dec. 30, 2022, in the Korean Intellectual Property Office, the disclosure of which is incorporated by reference herein in its entirety.

### BACKGROUND

### 1. Field

One or more embodiments relate to a display apparatus having improved flexibility.

### 2. Description of the Related Art

Electronic devices based on mobility have come into widespread use. Recently, tablet personal computers (PCs), in addition to small-sized electronic devices, such as a mobile phone, have been widely used as the mobile electronic devices.

To support various functions, for example, to provide a user with visual information, such as images or videos, the mobile electronic devices include a display. Recently, as components for driving such displays have become miniaturized, occupancy of the displays in electronic devices is gradually increasing.

Flexible display apparatuses capable of being bent, folded, or rolled have been recently researched and developed. Further, research and development of a stretchable display apparatus capable of being changed into various shapes is being actively conducted.

### SUMMARY

One or more embodiments include a display apparatus having improved flexibility.

Additional aspects will be set forth in part in the description that follows and, in part, will be apparent from the description, or may be learned by practice of the presented embodiments of the disclosure.

According to one or more embodiments, a display apparatus includes a substrate including a first pixel area and a second pixel area spaced from each other, and a first connection area between the first pixel area and the second pixel area, a 1-1^{st} electrode in the first pixel area, a 1-2^{nd} electrode in the second pixel area, a second electrode above the 1-1^{st} electrode and the 1-2^{nd} electrode, and extending in the first pixel area, the second pixel area, and the first connection area, a pattern layer above the second electrode in the first connection area, and biased from a center portion of the first connection area toward the first pixel area or the second pixel area, in plan view, and an encapsulation layer covering the pattern layer, and extending in the first pixel area, the second pixel area, and the first connection area.

The display apparatus may further include a capping layer in the first pixel area and the second pixel area.

The pattern layer may be spaced from the capping layer in plan view.

The capping layer may be above a portion of the second electrode in the first pixel area and the second pixel area, wherein the pattern layer is above another portion of the second electrode in the first connection area.

The pattern layer may include a same material as the capping layer.

The first connection area may include a first area including the center portion, a second area contacting the first pixel area or the second pixel area, and a third area between the first area and the second area, wherein the pattern layer is in the third area.

The second area may include a 2-1^{st} area contacting the first pixel area, and a 2-2^{nd} area contacting the second pixel area, wherein the third area includes a 3-1^{st} area between the first area and the 2-1^{st} area, and a 3-2^{nd} area between the first area and the 2-2^{nd} area, and wherein the pattern layer includes a first pattern layer in the 3-1^{st} area, and a second pattern layer in the 3-2^{nd} area.

An adhesive strength between the encapsulation layer and the pattern layer may be different from an adhesive strength between the encapsulation layer and the second electrode.

The adhesive strength between the encapsulation layer and the pattern layer may be less than the adhesive strength between the encapsulation layer and the second electrode.

The display apparatus may further include a first intermediate layer between the 1-1^{st} electrode and the second electrode, and a second intermediate layer between the 1-2^{nd} electrode and the second electrode.

According to one or more embodiments, a display apparatus includes a substrate including a first pixel area and a second pixel area spaced from each other in a first direction, and a first connection area extending in the first direction between the first pixel area and the second pixel area, a 1-1^{st} electrode in the first pixel area, a 1-2^{nd} electrode in the second pixel area, a second electrode above the 1-1^{st} electrode and the 1-2^{nd} electrode, and extending in the first pixel area, the second pixel area, and the first connection area, sub-pattern layers spaced from each other in the first direction above the second electrode in the first connection area, biased from a center portion of the first connection area toward the first pixel area or the second pixel area in plan view, and extending in a second direction crossing the first direction, and an encapsulation layer covering the sub-pattern layers, and extending in the first pixel area, the second pixel area, and the first connection area.

The display apparatus may further include a capping layer in the first pixel area and the second pixel area.

The sub-pattern layers may be spaced from the capping layer in plan view.

The capping layer may be above a portion of the second electrode in the first pixel area and the second pixel area, wherein the sub-pattern layers are above another portion of the second electrode in the first connection area.

The sub-pattern layers may include a same material as the capping layer.

The first connection area may include a first area including the center portion, a second area contacting the first pixel area or the second pixel area, and a third area between the first area and the second area, wherein the sub-pattern layers are in the third area.

The second area may include a 2-1^{st} area contacting the first pixel area, and a 2-2^{nd} area contacting the second pixel area, wherein the third area includes a 3-1^{st} area between the first area and the 2-1^{st} area, and a 3-2^{nd} area between the first area and the 2-2^{nd} area, and wherein some of the sub-pattern layers are in the 3-1^{st} area, and others of the sub-pattern layers are in the 3-2^{nd} area.

An adhesive strength between the encapsulation layer and the sub-pattern layers may be different from an adhesive strength between the encapsulation layer and the second electrode.

The adhesive strength between the encapsulation layer and the sub-pattern layers may be less than the adhesive strength between the encapsulation layer and the second electrode.

The display apparatus may further include a first intermediate layer between the 1-1^{st} electrode and the second electrode, and a second intermediate layer between the 1-2^{nd} electrode and the second electrode.

These and other aspects will become apparent and more readily appreciated from the following description of the embodiments, the claims, and the accompanying drawings.

### BRIEF DESCRIPTION OF THE DRAWINGS

The above and other aspects of certain embodiments of the disclosure will be more apparent from the following description taken in conjunction with the accompanying drawings, in which:

FIG. 1 is a schematic plan view of a display apparatus according to one or more embodiments;

FIG. 2 is a schematic plan view of a display apparatus according to one or more embodiments after an external force is applied to the display apparatus;

FIG. 3 is a schematic perspective view of a display apparatus according to one or more embodiments after an external force is applied to the display apparatus;

FIG. 4 is a schematic equivalent circuit diagram of a pixel circuit applicable to a display apparatus according to one or more embodiments;

FIG. 5 is a schematic magnified view of a portion A of the display apparatus of FIG. 1;

FIG. 6 is a cross-sectional view schematically illustrating cross-sections of the display apparatus of FIG. 5 respectively taken along the lines I-I′, II-II′, and III-III′;

FIG. 7 is a schematic magnified view of a portion B of FIG. 5;

FIG. 8 is a schematic cross-sectional view of a portion of a display apparatus according to one or more embodiments;

FIG. 9 is a schematic plan view of a portion of a display apparatus according to one or more embodiments; and

FIG. 10 is a schematic plan view of a portion of a display apparatus according to one or more embodiments.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in different forms, and should not be construed as being limited to only the illustrated embodiments herein. Further, each of the features of the various embodiments of the present disclosure may be combined or combined with each other, in part or in whole, and technically various interlocking and driving are possible. Each embodiment may be implemented independently of each other or may be implemented together in an association. The described embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions, such as “at least one of,” or “any one of,” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression, such as “at least one of A and B” and “at least one of A or B” may include A, B, or A and B. As used herein, “or” generally means “and/or,” and the term “and/or” includes any and all combinations of one or more of the associated listed items. For example, the expression, such as “A and/or B” may include A, B, or A and B. Similarly, expressions, such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

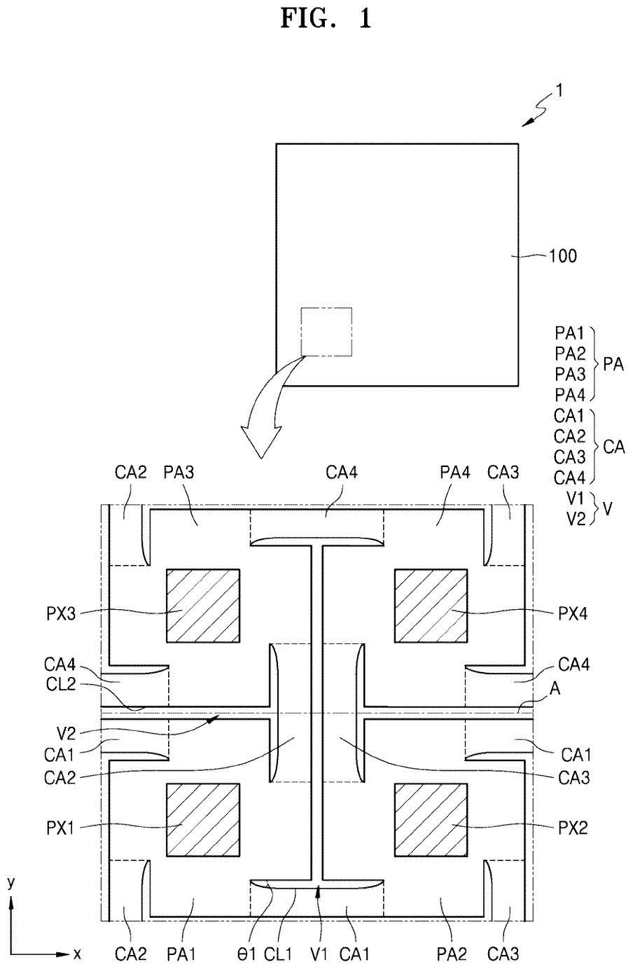

FIG. 1 is a schematic plan view of a display apparatus 1 according to one or more embodiments. The display apparatus 1, which are apparatuses for displaying an image, may be a portable mobile apparatus, such as a game player, a multimedia apparatus, and a subminiature personal computer (PC). Examples of the display apparatus 1 to be described below may include liquid crystal displays (LCDs), electrophoretic displays, organic light-emitting displays, inorganic light-emitting displays, field emission displays, surface-conduction electron-emitter displays, plasma displays, and cathode ray displays. Although an organic light-emitting display will now be illustrated and described as the display apparatus 1 according to one or more embodiments, various types of display apparatuses as described above may be used in embodiments.

Referring to FIG. 1, the display apparatus 1 may include a pixel area PA and a connection area CA. The pixel area PA may include a first pixel area PA1, a second pixel area PA2, a third pixel area PA3, and a fourth pixel area PA4, and the connection area CA may include a first connection area CA1, a second connection area CA2, a third connection area CA3, and a fourth connection area CA4.

A plurality of pixels may be arranged in the pixel area PA. For example, a first pixel PX1 may be located in the first pixel area PA1, a second pixel PX2 may be located in the second pixel area PA2, a third pixel PX3 may be located in the third pixel area PA3, and a fourth pixel PX4 may be located in the fourth pixel area PA4. The display apparatus 1 may provide an image by using light emitted by the pixels. For example, each of the pixels may emit red light, green light, or blue light.

The connection area CA may connect the first pixel area PA1, the second pixel area PA2, the third pixel area PA3, and the fourth pixel area PA4 to each other. In detail, the first connection area CA1 may connect the first pixel area PA1 to the second pixel area PA2, the second connection area CA2 may connect the first pixel area PA1 to the third pixel area PA3, the third connection area CA3 may connect the second pixel area PA2 to the fourth pixel area PA4, and the fourth connection area CA4 may connect the third pixel area PA3 to the fourth pixel area PA4. A separation region V may be defined in the display apparatus 1. The separation region V may pass through the display apparatus 1. The separation region V may be a region in which components of the display apparatus 1 are not arranged. The display apparatus 1 may be elongated and/or contracted by the separation region V.

Referring to FIG. 1, the display apparatus 1 may include the substrate 100. Because the display apparatus 1 includes the substrate 100, it may be considered that the substrate 100 has the pixel area PA and the connection area CA and the separation region V is defined in the substrate 100. For convenience of explanation, it will now be described that the substrate 100 includes the pixel area PA and the connection area CA and the separation region V is defined in the substrate 100.

The substrate 100 may include any of various materials, such as glass, metal, or an organic material. According to one or more embodiments, the substrate 100 may include a flexible material. For example, the substrate 100 may include ultra-thin flexible glass (e.g., a thickness of tens to hundreds of um) or polymer resin. When the substrate 100 includes polymer resin, the substrate 100 may include polymer resin, such as polyethersulfone, polyarylate, polyetherimide, polyethylene naphthalate, polyethylene terephthalate, polyphenylene sulfide, polyimide, polycarbonate, or cellulose acetate propionate.

As described above, the substrate 100 may include the pixel area PA and the connection area CA. The pixel area PA may include the first pixel area PA1, the second pixel area PA2, the third pixel area PA3, and the fourth pixel area PA4, and the connection area CA may include the first connection area CA1, the second connection area CA2, the third connection area CA3, and the fourth connection area CA4.

The first pixel area PA1, the second pixel area PA2, the third pixel area PA3, and the fourth pixel area PA4 may be spaced apart from each other in a first direction and/or a second direction. The first direction and the second direction may intersect with each other. For example, the first direction and the second direction may form an acute angle. Alternatively, the first direction and the second direction may form an obtuse angle or a right angle. For convenience of explanation, a case where the first direction and the second direction are substantially perpendicular to each other will now be focused on and described. For example, the first direction may be a +x direction (or a −x direction that is opposite thereto), and the second direction may be a +y direction (or a −y direction that is opposite thereto).

In detail, the first pixel area PA1 and the second pixel area PA2 may be spaced apart from each other in the first direction (for example, the +x direction or the −x direction). The first pixel area PA1 and the third pixel area PA3 may be spaced apart from each other in the second direction (for example, the +y direction or the −y direction). The first pixel area PA1 and the fourth pixel area PA4 may be spaced apart from each other in the first direction (e.g., the +x direction or the −x direction) and the second direction (e.g., the +y direction or the −y direction). Accordingly, the fourth pixel area PA4 may be spaced apart from the third pixel area PA3 in the first direction (for example, the +x direction or the −x direction), and the fourth pixel area PA4 may be spaced apart from the second pixel area PA2 in the second direction (for example, the +y direction or the −y direction).

Each of the first pixel area PA1, the second pixel area PA2, the third pixel area PA3, and the fourth pixel area PA4 may have a polygonal shape. In FIG. 1, each of the first pixel area PA1, the second pixel area PA2, the third pixel area PA3, and the fourth pixel area PA4 has a polygon having twelve sides (for example, an approximately cross shape). However, the disclosure is not limited thereto. For example, each of the first pixel area PA1, the second pixel area PA2, the third pixel area PA3, and the fourth pixel area PA4 may have a triangular, rectangular, or circular shape. For convenience of explanation, a case where each of the first pixel area PA1, the second pixel area PA2, the third pixel area PA3, and the fourth pixel area PA4 has an approximately cross shape will now be focused on and described.

Adjacent areas among the first pixel area PA1, the second pixel area PA2, the third pixel area PA3, and the fourth pixel area PA4 may be symmetrical to each other. For example, in FIG. 1, the first pixel area PA1 and the second pixel area PA2 laterally adjacent to each other may be laterally symmetric to each other about an axis of symmetry that is located between the first pixel area PA1 and the second pixel area PA2 and that is parallel to the second direction (e.g., the +y direction or the −y direction). In FIG. 1, the third pixel area PA3 and the fourth pixel area PA4 laterally adjacent to each other may be laterally symmetric to each other about an axis of symmetry that is located between the third pixel area PA3 and the fourth pixel area PA4 and that is parallel to the second direction (e.g., the +y direction or the −y direction).

Likewise, in FIG. 1, the first pixel area PA1 and the third pixel area PA3 vertically adjacent to each other may be vertically symmetric to each other about an axis of symmetry that is located between the first pixel area PA1 and the third pixel area PA3 and that is parallel to the first direction (e.g., the +x direction or the −x direction). In FIG. 1, the second pixel area PA2 and the fourth pixel area PA4 vertically adjacent to each other may be vertically symmetric to each other about an axis of symmetry that is located between the second pixel area PA2 and the fourth pixel area PA4 and that is parallel to the first direction (e.g., the +x direction or the −x direction).

The first pixel PX1, the second pixel PX2, the third pixel PX3, and the fourth pixel PX4 may be located on the first pixel area PA1, the second pixel area PA2, the third pixel area PA3, and the fourth pixel area PA4, respectively. In detail, the first pixel PX1 may be located on the first pixel area PA1, and the second pixel PX2 may be located on the second pixel area PA2. The third pixel PX3 may be located on the third pixel area PA3, and the fourth pixel PX4 may be located on the fourth pixel area PA4.

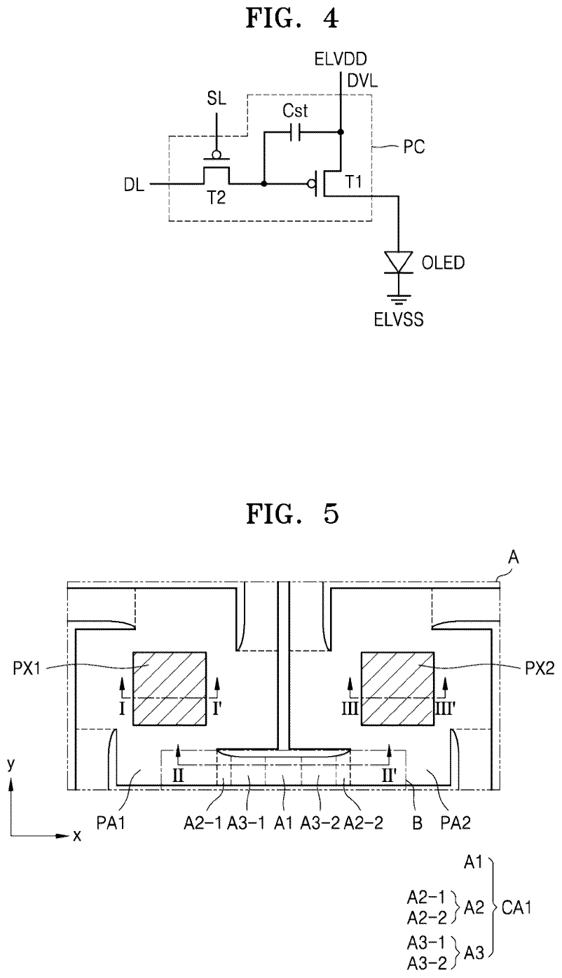

According to one or more embodiments, each of the first pixel PX1, the second pixel PX2, the third pixel PX3, and the fourth pixel PX4 may include one organic light-emitting diode OLED (e.g., see FIG. 4) for emitting red, blue, green, or white light. Accordingly, each of the first pixel PX1, the second pixel PX2, the third pixel PX3, and the fourth pixel PX4 may be a sub-pixel. However, the disclosure is not limited thereto.

According to one or more embodiments, each of the first pixel PX1, the second pixel PX2, the third pixel PX3, and the fourth pixel PX4 may include a plurality of organic light-emitting diodes OLED for emitting different light beams. For example, each of the first pixel PX1, the second pixel PX2, the third pixel PX3, and the fourth pixel PX4 may include all of an organic light-emitting diode OLED for emitting red light, an organic light-emitting diode OLED emitting green light, and an organic light-emitting diode OLED emitting blue light. The organic light-emitting diodes OLED within the first pixel PX1, the second pixel PX2, the third pixel PX3, and the fourth pixel PX4 may be arranged in various configurations, such as an RGB configuration, a PenTile™ structure (e.g., a PENTILE™ matrix structure, a PENTILE™ structure, or an RGBG structure, PENTILE™ BEING a registered trademark of Samsung Display Co., Ltd., Republic of Korea), and a honeycomb structure, according to the efficiency of a material included in an organic emission layer.

The first pixel area PA1, the second pixel area PA2, the third pixel area PA3, and the fourth pixel area PA4 may be connected to (e.g., coupled to) each other by the first connection area CA1, the second connection area CA2, the third connection area CA3, and/or the fourth connection area CA4. In detail, the first connection area CA1 may connect the first pixel area PA1 to the second pixel area PA2, and the second connection area CA2 may connect the first pixel area PA1 to the third pixel area PA3. The third connection area CA3 may connect the second pixel area PA2 to the fourth pixel area PA4, and the fourth connection area CA4 may connect the third pixel area PA3 to the fourth pixel area PA4.

The first connection area CA1 may extend from the first pixel area PA1 to the second pixel area PA2. The first pixel area PA1 and the second pixel area PA2 may be connected to each other by the first connection area CA1. The second connection area CA2 may extend from the first pixel area PA1 to the third pixel area PA3. The first pixel area PA1 and the third pixel area PA3 may be connected to each other by the second connection area CA2. The third connection area CA3 may extend from the second pixel area PA2 to the fourth pixel area PA4. The second pixel area PA2 and the fourth pixel area PA4 may be connected to each other by the third connection area CA3. The fourth connection area CA4 may extend from the third pixel area PA3 to the fourth pixel area PA4. The third pixel area PA3 and the fourth pixel area PA4 may be connected to each other by the fourth connection area CA4.

For example, the first connection area CA1 connected to the first pixel area PA1 may extend in the first direction (for example, the +x direction or the −x direction), and thus may be connected to (e.g., coupled to) the second pixel area PA2 located adjacent to the first pixel area PA1. Similarly, the second connection area CA2 connected to the first pixel area PA1 may extend in the second direction (for example, the +y direction or the −y direction), and thus may be connected to the third pixel area PA3 located adjacent to the first pixel area PA1. Similarly, the third connection area CA3 connected to the second pixel area PA2 may extend in the second direction (for example, the +y direction or the −y direction), and thus may be connected to the fourth pixel area PA4 located adjacent to the second pixel area PA2. Similarly, the fourth connection area CA4 connected to the third pixel area PA3 may extend in the first direction (for example, the +x direction or the −x direction), and thus may be connected to the fourth pixel area PA4 located adjacent to the third pixel area PA3.

The first pixel area PA1, the second pixel area PA2, the third pixel area PA3, and the fourth pixel area PA4, and the first connection area CA1, the second connection area CA2, the third connection area CA3, and the fourth connection area CA4, may be consecutively formed of the same materials. The first pixel area PA1, the second pixel area PA2, the third pixel area PA3, and the fourth pixel area PA4, and the first connection area CA1, the second connection area CA2, the third connection area CA3, and the fourth connection area CA4, may be integrally included. Accordingly, the first pixel area PA1, the second pixel area PA2, the third pixel area PA3, and the fourth pixel area PA4 may be integrally formed with the first connection area CA1, the second connection area CA2, the third connection area CA3, and the fourth connection area CA4.

The first pixel area PA1, the second pixel area PA2, the third pixel area PA3, the fourth pixel area PA4, the first connection area CA1, the second connection area CA2, the third connection area CA3, and the fourth connection area CA4 may be repeatedly arranged in the first direction (for example, the +x direction or the −x direction) and in the second direction (for example, the +y direction or the −y direction). Thus, it may be understood that, in the display apparatus 1, the first pixel area PA1, the second pixel area PA2, the third pixel area PA3, the fourth pixel area PA4, the first connection area CA1, the second connection area CA2, the third connection area CA3, and the fourth connection area CA4, which are repeatedly arranged, are connected to each other and included. Accordingly, the first connection area CA1 connected to a left upper portion of the first pixel area PA1 of FIG. 1 connects the first pixel area PA1 to another second pixel area PA2 located in the −x direction of the first pixel area PA1. The second connection area CA2 connected to a left lower portion of the first pixel area PA1 of FIG. 1 connects the first pixel area PA1 to another third pixel area PA3 located in the −y direction of the first pixel area PA1.

Similarly, the first connection area CA1 connected to a right upper portion of the second pixel area PA2 of FIG. 1 connects the second pixel area PA2 to anther first pixel area PA1 located in the +x direction of the second pixel area PA2. The third connection area CA3 connected to a right lower portion of the second pixel area PA2 of FIG. 1 connects the second pixel area PA2 to another fourth pixel area PA4 located in the −y direction of the second pixel area PA2. Similarly, the second connection area CA2 connected to a left upper portion of the third pixel area PA3 of FIG. 1 connects the third pixel area PA3 to another first pixel area PA1 located in the +y direction of the third pixel area PA3. The fourth connection area CA4 connected to a left lower portion of the third pixel area PA3 of FIG. 1 connects the third pixel area PA3 to another fourth pixel area PA4 located in the −x direction of the third pixel area PA3. Similarly, the third connection area CA3 connected to a right upper portion of the fourth pixel area PA4 of FIG. 1 connects the fourth pixel area PA4 to another second pixel area PA2 located in the +y direction of the fourth pixel area PA4. The fourth connection area CA4 connected to a right lower portion of the fourth pixel area PA4 of FIG. 1 connects the fourth pixel area PA4 to another third pixel area PA3 located in the +x direction of the fourth pixel area PA4.

Thus, one first pixel area PA1 may be connected to a pair of first connection areas CA1 respectively located on opposite sides of the first pixel area PA1 and each extending in a direction parallel to the first direction (for example, the +x direction or the −x direction), and may be connected to a pair of second connection areas CA2 respectively located on opposite sides of the first pixel area PA1 and each extending in a direction parallel to the second direction (for example, the +y direction or the −y direction). Similarly, one second pixel area PA2 may be connected to a pair of first connection areas CA1 respectively located on opposite sides of the second pixel area PA2 and each extending in the direction parallel to the first direction (for example, the +x direction or the −x direction), and may be connected to a pair of third connection areas CA3 respectively located on opposite sides of the second pixel area PA2 and each extending in the direction parallel to the second direction (for example, the +y direction or the −y direction).

Similarly, one third pixel area PA3 may be connected to a pair of fourth connection areas CA4 respectively located on opposite sides of the third pixel area PA3 and each extending in the direction parallel to the first direction (for example, the +x direction or the −x direction), and may be connected to a pair of second connection areas CA2 respectively located on opposite sides of the third pixel area PA3 and each extending in the direction parallel to the second direction (for example, the +y direction or the −y direction). Similarly, one fourth pixel area PA4 may be connected to a pair of fourth connection areas CA4 respectively located on opposite sides of the fourth pixel area PA4 and each extending in the direction parallel to the first direction (for example, the +x direction or the −x direction), and may be connected to a pair of third connection areas CA3 respectively located on opposite sides of the fourth pixel area PA4 and each extending in the direction parallel to the second direction (for example, the +y direction or the −y direction).

Respective edges of the first pixel area PA1, the second pixel area PA2, the third pixel area PA3, and the fourth pixel area PA4, and respective edges of the first connection area CA1, the second connection area CA2, the third connection area CA3, and the fourth connection area CA4, may define a separation region V. The separation region V may include a first separation region V1 and a second separation region V2. In detail, closed loops may be formed by the respective edges of the first pixel area PA1, the second pixel area PA2, the third pixel area PA3, the fourth pixel area PA4, the first connection area CA1, the second connection area CA2, the third connection area CA3, and the fourth connection area CA4. These closed loops may define the separation region V.

For example, a first closed loop CL1 including an edge of the first pixel area PA1 in the +x direction, an edge of the first connection area CA1 in the +y direction, an edge of the second pixel area PA2 in the −x direction, an edge of the third connection area CA3 in the −x direction, an edge of the fourth pixel area PA4 in the −x direction, an edge of the fourth connection area CA4 in the −y direction, an edge of the third pixel area PA3 in the +x direction, and an edge of the second connection area CA2 in the +x direction may be formed. The first closed loop CL1 may define the first separation region V1, which is an empty space.

Similarly, a second closed loop CL2 including an edge of the first pixel area PA1 in the +x direction, an edge of the third connection area CA3 in the −x direction, an edge of the third pixel area PA3 in the −y direction, an edge of the fourth connection area CA4 in the −y direction, an edge of the fourth pixel area PA4 in the −y direction, an edge of the third connection area CA3 in the +x direction, an edge of the second pixel area PA2 in the +y direction, and an edge of the first connection area CA1 in the +y direction may be formed. The second closed loop CL2 may define the second separation region V2, which is an empty space.

Accordingly, the first separation region V1 may have an H shape rotated 90 degrees clockwise, and the second separation region V2 may have an H shape. However, the disclosure is not limited thereto.

According to one or more embodiments, an angle between the edge of the first pixel area PA1 and the edge of the first connection area CA1 may be a first angle 81, and the first angle 61 may be an acute angle. An angle between the edge of the first pixel area PA1 and the edge of the second connection area CA2, an angle between the edge of the second pixel area PA2 and the edge of the first connection area CA1, an angle between the edge of the second pixel area PA2 and the edge of the third connection area CA3, an angle between the edge of the third pixel area PA3 and the edge of the second connection area CA2, an angle between the edge of the third pixel area PA3 and the edge of the fourth connection area CA4, an angle between the edge of the fourth pixel area PA4 and the edge of the third connection area CA3, and an angle between the edge of the fourth pixel area PA4 and the edge of the fourth connection area CA4 may be the same as, or similar to, the first angle 81.

The separation region V may pass through the substrate 100. In detail, the separation region V may pass through an upper surface and a lower surface of the substrate 100. The separation region V may provide separation between the first pixel area PA1, the second pixel area PA2, the third pixel area PA3, and the fourth pixel area PA4. In detail, the first separation region V1 may provide separation between the first pixel area PA1 and the second pixel area PA2, and separation between the third pixel area PA3 and the fourth pixel area PA4. The second separation region V2 may provide separation between the first pixel area PA1 and the third pixel area PA3, and separation between the second pixel area PA2 and the fourth pixel area PA4. Accordingly, the separation region V may reduce the weight of the substrate 100, and may improve the flexibility of the substrate 100.

When the substrate 100 is bent, rolled, or the like, the shape of the separation region V may change. Thus, stress generation during deformation of the substrate 100 may be suitably reduced. Thus, abnormal deformation of the substrate 100 may be reduced or prevented, and durability of the substrate 100 may improve. Accordingly, when the display apparatus 1 is used, user convenience may improve, and the display apparatus 1 may be suitably applied to wearable devices.

The separation region V may be formed by removing one region of the substrate 100 via etching or the like. As another example, the separation region V may be formed to be included, during the manufacture of the substrate 100. The separation region V may be formed in the substrate 100 in various ways, and a method of forming the separation region V is not limited.

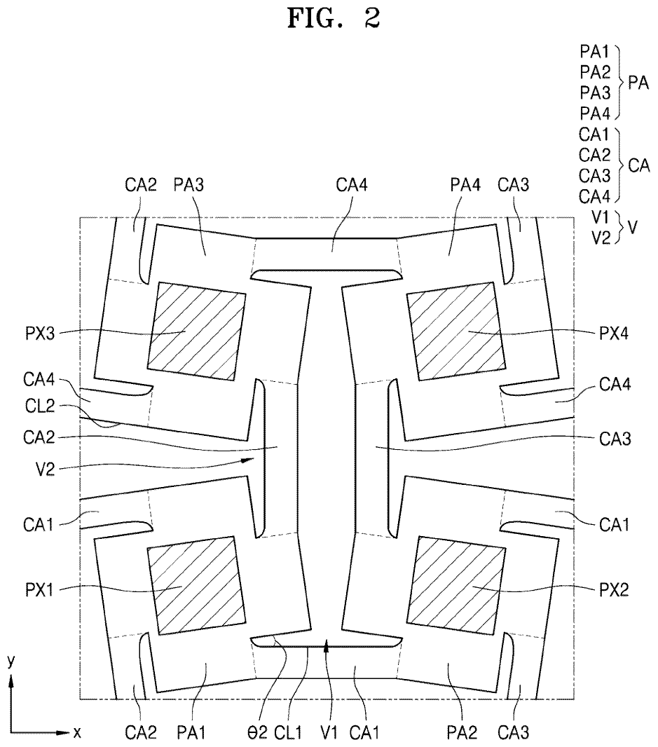

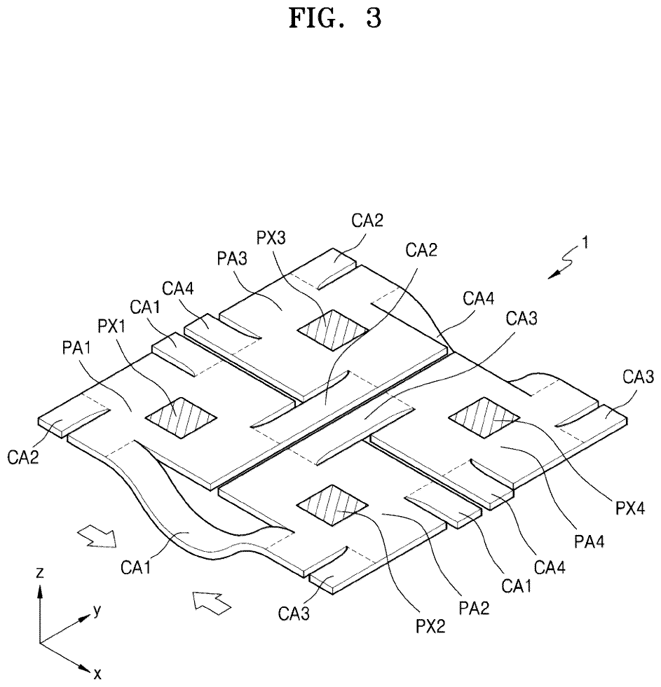

When an external force is applied to the display apparatus 1, the locations and/or shapes of the components included in the substrate 100 may be changed. FIG. 2 is a schematic plan view of the display apparatus 1 according to one or more embodiments after an external force is applied to the display apparatus 1, and FIG. 3 is a schematic perspective view of the display apparatus 1 according to one or more embodiments after an external force is applied to the display apparatus 1. In detail, FIG. 2 illustrates a shape of the display apparatus 1 when the substrate 100 is stretched in the first direction (for example, the +x direction or the −x direction) and in the second direction (for example, the +y direction or the −y direction).

Referring to FIG. 2, when an external force, such as a tensile force is applied to the substrate 100, the angle between the edge of the first pixel area PA1 and the edge of the first connection area CA1 may be a second angle 82. The second angle 82 may be greater than the first angle 81. In other words, when an external force, such as a tensile force is applied to the substrate 100, the angle between the edge of the first pixel area PA1 and the edge of the first connection area CA1 may increase.

Similarly, the angle between the edge of the first pixel area PA1 and the edge of the second connection area CA2, the angle between the edge of the second pixel area PA2 and the edge of the first connection area CA1, the angle between the edge of the second pixel area PA2 and the edge of the third connection area CA3, the angle between the edge of the third pixel area PA3 and the edge of the second connection area CA2, the angle between the edge of the third pixel area PA3 and the edge of the fourth connection area CA4, the angle between the edge of the fourth pixel area PA4 and the edge of the third connection area CA3, and the angle between the edge of the fourth pixel area PA4 and the edge of the fourth connection area CA4, may also increase.

Thus, the area of the separation region V may be increased. Accordingly, an interval between the first pixel area PA1 and the third pixel area PA3, an interval between the second pixel area PA2 and the fourth pixel area PA4, an interval between the first pixel area PA1 and the second pixel area PA2, and an interval between the third pixel area PA3 and the fourth pixel area PA4 may be increased.

When the substrate 100 is stretched, stress may be concentrated on a portion of the first connection area CA1 connected to the edge of the first pixel area PA1. When the substrate 100 is stretched, stress may also be concentrated on a portion of the second connection area CA2 connected to the edge of the first pixel area PA1, a portion of the first connection area CA1 connected to the edge of the second pixel area PA2, a portion of the third connection area CA3 connected to the edge of the second pixel area PA2, a portion of the second connection area CA2 connected to the edge of the third pixel area PA3, a portion of the fourth connection area CA4 connected to the edge of the third pixel area PA3, a portion of the third connection area CA3 connected to the edge of the fourth pixel area PA4, and/or a portion of the fourth connection area CA4 connected to the edge of the fourth pixel area PA4. The first closed loop CL1 defining the first separation region V1 and the second closed loop CL2 defining the second separation region V2 may reduce or prevent the likelihood of the first connection area CA1 or the like being torn due to this stress concentration.

Referring to FIG. 3, when an external force, such as a compression force, is applied to the substrate 100, the substrate 100 may be deformed in the third direction (for example, the +z direction or the −z direction). For example, when an external force, such as a compression force is applied to the substrate 100, the first connection area CA1 and the fourth connection area CA4 may be bent. Accordingly, at least a portion of the first connection area CA1 and at least a portion of the fourth connection area CA4 may move in a third direction (for example, a +z direction or a −z direction). In detail, a center portion of the first connection area CA1 may move farthest from the first pixel area PA1 and the second pixel area PA2 in the third direction (for example, the +z direction or the −z direction). In a direction from the center portion of the first connection area CA1 to the first pixel area PA1 or the second pixel area PA2, the movement in the third direction (for example, the +z direction or the −z direction) may be reduced. In this case, a distance between the first pixel area PA1 and the second pixel area PA2 adjacent to each other may decrease.

The above description of the change in the first connection area CA1 when an external force, such as a compression force, is applied to the substrate 100 is equally applicable to the second connection area CA2, the third connection area CA3, and the fourth connection area CA4. The above description of the change in the distance between the first pixel area PA1 and the second pixel area PA2 when an external force, such as a compression force, is applied to the substrate 100 is equally applicable to a distance between the first pixel area PA1 and the third pixel area PA3, a distance between the second pixel area PA2 and the fourth pixel area PA4, and a distance between the third pixel area PA3 and the fourth pixel area PA4. Thus, repeated descriptions thereof will be omitted.

In other words, when an external force is applied to the substrate 100, the locations and/or shapes of the components included in the substrate 100 may be changed two-dimensionally or three-dimensionally. In detail, an area and a shape of the separation region V may be changed, and respective locations and respective shapes of the first connection area CA1, the second connection area CA2, the third connection area CA3, and the fourth connection area CA4 may be changed. Accordingly, respective locations of the first pixel area PA1, the second pixel area PA2, the third pixel area PA3, and the fourth pixel area PA4 may be changed. The first connection area CA1, the second connection area CA2, the third connection area CA3, and the fourth connection area CA4 are formed to have widths that are less than those of the first pixel area PA1, the second pixel area PA2, the third pixel area PA3, and the fourth pixel area PA4. Thus, a shape change when an external force is applied to the substrate 100 may mainly appear in the first connection area CA1, the second connection area CA2, the third connection area CA3, and the fourth connection area CA4, and respective shapes of the first pixel area PA1, the second pixel area PA2, the third pixel area PA3, and the fourth pixel area PA4 may not change. Accordingly, the first pixel PX1, the second pixel PX2, the third pixel PX3, and the fourth pixel PX4 respectively located on the first pixel area PA1, the second pixel area PA2, the third pixel area PA3, and the fourth pixel area PA4 may be stably maintained even when an external force is applied to the substrate 100.

FIG. 4 is a schematic equivalent circuit diagram of a pixel circuit PC applicable to the display apparatus 1 according to one or more embodiments.

Referring to FIG. 4, the pixel circuit PC may be connected to a display element, for example, an organic light-emitting diode OLED. The pixel circuit PC may include a driving thin-film transistor T1, a switching thin-film transistor T2, and a storage capacitor Cst. The organic light-emitting diode OLED may emit red light, green light, or blue light, or may emit red light, green light, blue light, or white light.

The switching thin-film transistor T2 may be connected to a scan line SL and a data line DL, and may transmit, to the driving thin-film transistor T1, a data signal or data voltage received via the data line DL according to a scan signal or switching voltage received via the scan line SL. The storage capacitor Cst may be connected to the switching thin-film transistor T2 and a driving voltage line DVL, and may store a voltage corresponding to a difference between a voltage received from the switching thin-film transistor T2 and a first power supply voltage ELVDD supplied to the driving voltage line DVL.

The driving thin-film transistor T1 is connected to the driving voltage line DVL and the storage capacitor Cst, and may control a driving current flowing from the driving voltage line DVL to the organic light-emitting diode OLED, in accordance with a voltage value stored in the storage capacitor Cst. The organic light-emitting diode OLED may emit light having a certain brightness according to the driving current. An opposite electrode of the organic light-emitting diode OLED may receive a second power supply voltage ELVSS.

In FIG. 4, the pixel circuit PC includes two thin-film transistors and one storage capacitor. However, the pixel circuit PC may include three, four, five, or more thin-film transistors.

FIG. 5 is a schematic plan view of the display apparatus 1 according to one or more embodiments. In detail, FIG. 5 is a schematic magnified view of a portion A of the display apparatus 1 of FIG. 1. The display apparatus 1 may include the substrate 100, and the substrate 100 may include the pixel area PA and the connection area CA. In detail, the substrate 100 may include the first pixel area PA1, the second pixel area PA2, the third pixel area PA3, the fourth pixel area PA4, the first connection area CA1, the second connection area CA2, the third connection area CA3, and the fourth connection area CA4.

The description of the first pixel area PA1 is applicable to the second pixel area PA2, the third pixel area PA3, and the fourth pixel area PA4, and the description of the first connection area CA1 is applicable to the second connection area CA2, the third connection area CA3, and the fourth connection area CA4. Accordingly, the first pixel area PA1, the second pixel area PA2, which is another pixel area adjacent to the first pixel area PA1, and the first connection area CA1 connecting the first pixel area PA1 to the second pixel area PA2, will now be focused on and described. A description of a relationship between the first pixel area PA1, the second pixel area PA2, and the first connection area CA1 is equally applicable to a relationship between the first pixel area PA1, the third pixel area PA3, and the second connection area CA2, a relationship between the second pixel area PA2, the fourth pixel area PA4, and the third connection area CA3, and a relationship between the third pixel area PA3, the fourth pixel area PA4, and the fourth connection area CA4.

Referring to FIG. 5, the first pixel area PA1 and the other pixel area adjacent to the first pixel area PA1 may be spaced apart from each other. In detail, the first pixel area PA1 and the second pixel area PA2 may be spaced apart from each other. The first pixel area PA1 and the second pixel area PA2 may be spaced apart from each other in the first direction (for example, the +x direction or the −x direction). Each of the first pixel area PA1 and the second pixel area PA2 may be in the shape of a 12-sided polygon (for example, an approximately cross). The first pixel area PA1 and the second pixel area PA2, which are laterally adjacent to each other, may be laterally symmetric to each other about an axis of symmetry that is located between the first pixel area PA1 and the second pixel area PA2 and that is parallel to the second direction (e.g., the +y direction or the −y direction).

The first pixel PX1 and the second pixel PX2 may be located on the first pixel area PA1 and the second pixel area PA2, respectively. In detail, the first pixel PX1 may be located on the first pixel area PA1, and the second pixel PX2 may be located on the second pixel area PA2. Each of the first pixel PX1 and the second pixel PX2 may include one organic light-emitting diode OLED for emitting red, blue, green, or white light.

The first connection area CA1 may be located between the first pixel area PA1 and the second pixel area PA2. In detail, the first connection area CA1 may extend from the first pixel area PA1 to the second pixel area PA2. The first pixel area PA1 and the second pixel area PA2 may be connected to each other by the first connection area CA1. For example, the first connection area CA1 connected to the first pixel area PA1 may extend in the first direction (for example, the +x direction or the −x direction), and thus may be connected to the second pixel area PA2 located adjacent to the first pixel area PA1.

The first connection area CA1 may include a first area A1, a second area A2, and a third area A3. The first area A1 may include the center portion of the first connection area CA1. The center portion of the first connection area CA1 may include the center of the first connection area CA1. When the first connection area CA1 extends in the first direction (for example, the +x direction or the −x direction), a distance between one end of the first connection area CA1 in contact with the first pixel area PA1 and the center of the first connection area CA1 in the first direction (for example, the +x direction or the −x direction) may be about the same as a distance between the other end of the first connection area CA1 in contact with the second pixel area PA2 and the center of the first connection area CA1 in the first direction (for example, the +x direction or the −x direction).

Accordingly, when the first connection area CA1 extends in the first direction (for example, the +x direction or the −x direction), the center of the first connection area CA1 may be a portion of the first connection area CA1 in which a distance from the first pixel area PA1 in the first direction (for example, the +x direction or the −x direction) is the same as a distance from the second pixel area PA2 in the first direction (for example, the +x direction or the −x direction). The first area A1 of the first connection area CA1 may be a portion of the first connection area CA1 that is located farthest from the first pixel area PA1 and the second pixel area PA2 in the first direction (for example, the +x direction or the −x direction).

The second area A2 may be in contact with the first pixel area PA1 or the second pixel area PA2. The second area A2 may include a portion of the first connection area CA1 that is in contact with the first pixel area PA1 or the second pixel area PA2. The second area A2 of the first connection area CA1 may be an area located closest to the first pixel area PA1 or the second pixel area PA2 in the first direction (for example, the +x direction or the −x direction). The second area A2 may include a 2-1^{st} area A2-1 and a 2-2^{nd} area A2-2. The 2-1^{st} area A2-1 may be an area including a portion in contact with the first pixel area PA1, and the 2-2^{nd} area A2-2 may be an area including a portion in contact with the second pixel area PA2. The 2-1^{st} area A2-1 may be an area located closest to the first pixel area PA1, and the 2-2^{nd} area A2-2 may be an area located closest to the second pixel area PA2.

The third area A3 may be an area that is biased toward the first pixel area PA1 or the second pixel area PA2 based on the center of the first connection area CA1. The third area A3 may be an area located between the first area A1 and the second area A2. The third area A3 may include a 3-1^{st} area A3-1 and a 3-2^{nd} area A3-2. The 3-1^{st} area A3-1 may be an area that is biased toward the first pixel area PA1, and the 3-2^{nd} area A3-2 may be an area that is biased toward the second pixel area PA2. The 3-1^{st} area A3-1 may be an area located between the first area A1 and the 2-1^{st} area A2-1, and the 3-2^{nd} area A3-2 may be an area located between the first area A1 and the 2-2^{nd} area A2-2.

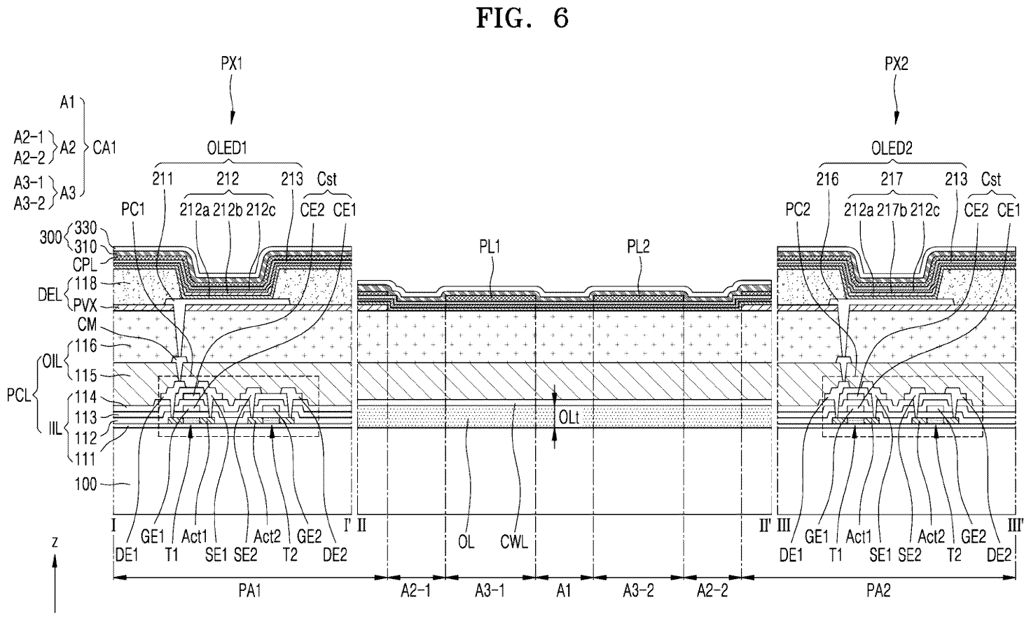

FIG. 6 is a schematic cross-sectional view of a portion of the display apparatus 1 according to one or more embodiments. In detail, FIG. 6 is a cross-sectional view schematically illustrating cross-sections of the display apparatus 1 of FIG. 5 respectively taken along the lines I-I′, II-II′, and III-III′.

Referring to FIG. 6, the display apparatus 1 may include the substrate 100, a pixel circuit layer PCL, a display element layer DEL, and an encapsulation layer 300.

The substrate 100 may include the pixel area PA and the connection area CA. The pixel area PA may include the first pixel area PA1, the second pixel area PA2, the third pixel area PA3, and the fourth pixel area PA4, and the connection area CA may include the first connection area CA1, the second connection area CA2, the third connection area CA3, and the fourth connection area CA4. As described above, the description of the first pixel area PA1 is applicable to the second pixel area PA2, the third pixel area PA3, and the fourth pixel area PA4, and the description of the first connection area CA1 is applicable to the second connection area CA2, the third connection area CA3, and the fourth connection area CA4, and thus the first pixel area PA1, the second pixel area PA2, which is the other pixel area adjacent to the first pixel area PA1, and the first connection area CA1 connecting the first pixel area PA1 to the second pixel area PA2 will be focused on and described.

Pixels may be arranged on the pixel area PA of the substrate 100. In detail, the first pixel PX1 may be located on the first pixel area PA1, and the second pixel PX2 may be located on the second pixel area PA2. Each of the first pixel PX1 and the second pixel PX2 may include a display element. In detail, the first pixel PX1 may include a first organic light-emitting diode OLED1 as a display element, and the second pixel PX2 may include a second organic light-emitting diode OLED2 as a display element. Each of the display elements may be electrically connected to one pixel circuit PC. In detail, the first organic light-emitting diode OLED1 may be electrically connected to a first pixel circuit PC1, and the second organic light-emitting diode OLED2 may be electrically connected to a second pixel circuit PC2.

Because respective structures of the first pixel circuit PC1 and the second pixel circuit PC2 are the same as, or similar to, each other, and because respective structures of the first organic light-emitting diode OLED1 and the second organic light-emitting diode OLED2 are the same as each other, the first pixel circuit PC1 and the first organic light-emitting diode OLED1 will be focused on and described.

The pixel circuit layer PCL may be located on the pixel area PA of the substrate 100. In detail, the pixel circuit layer PCL may be located on the first pixel area PA1 and the second pixel area PA2. The pixel circuit layer PCL may include pixel circuits. In detail, the first pixel circuit PC1 may be located on the first pixel area PA1, and the second pixel circuit PC2 may be located on the second pixel area PA2. According to one or more embodiments, the first pixel circuit PC1 may include the driving thin-film transistor T1, the switching thin-film transistor T2, and the storage capacitor Cst.

The pixel circuit layer PCL may include an inorganic insulating layer IIL and an organic insulating layer OIL located under and/or over elements of the driving thin-film transistor T1. The inorganic insulating layer IIL may include a buffer layer 111, a first gate-insulating layer 112, a second gate-insulating layer 113, and an interlayer insulating layer 114. The organic insulating layer OIL may include a first organic insulating layer 115 and a second organic insulating layer 116. The driving thin-film transistor T1 may include a first semiconductor layer Act1, a first gate electrode GE1, a first source electrode SE1, and a first drain electrode DE1.

The buffer layer 111 may be located on the pixel area PA. The buffer layer 111 may reduce or prevent impurities from penetrating into the first semiconductor layer Act1 of the driving thin-film transistor T1. The buffer layer 111 may include an inorganic insulating material, such as silicon nitride (SiNₓ), silicon oxynitride (SiON), or silicon oxide (SiO₂), and may have a single-layer or a multi-layer structure including the inorganic insulating material.

The first semiconductor layer Act1 may be located on the buffer layer 111. The first semiconductor layer Act1 may include polysilicon. Alternatively, the first semiconductor layer Act1 may include, for example, amorphous silicon, an oxide semiconductor, or an organic semiconductor. The first semiconductor layer Act1 may include a channel region, and a source region and a drain region respectively arranged on both sides of the channel region.

The first gate electrode GE1 may overlap the channel region. The first gate electrode GE1 may include a low-resistance metal material. The first gate electrode GE1 may include a conductive material including, for example, molybdenum (Mo), aluminum (Al), copper (Cu), and/or titanium (Ti), and may have a multi-layer or single-layer structure including the aforementioned materials.

The first gate-insulating layer 112 between the first semiconductor layer Act1 and the first gate electrode GE1 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO).

The second gate-insulating layer 113 may cover the first gate electrode GE1. Similar to the first gate-insulating layer 112, the second gate-insulating layer 113 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO).

An upper electrode CE2 of the storage capacitor Cst may be located on the second gate-insulating layer 113. The upper electrode CE2 may overlap the first gate electrode GE1 located therebelow. The first gate electrode GE1 of the driving thin-film transistor T1 and the upper electrode CE2, which overlap each other with the second gate-insulating layer 113 therebetween, may constitute the storage capacitor Cst. Accordingly, the first gate electrode GE1 of the driving thin-film transistor T1 may function as a lower electrode CE1 of the storage capacitor Cst.

As such, the storage capacitor Cst and the driving thin-film transistor T1 may overlap each other. According to one or more other embodiments, the storage capacitor Cst and the driving thin-film transistor T1 do not overlap each other.

The upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or a multi-layer including the aforementioned materials.

The interlayer insulating layer 114 may cover the upper electrode CE2. The interlayer insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO), or the like. The interlayer insulating layer 114 may be a single layer or multi-layer including the aforementioned inorganic insulating materials.

Each of the first drain electrode DE1 and the first source electrode SE1 may be located on the interlayer insulating layer 114. The first drain electrode DE1 and the first source electrode SE1 may include a highly conductive material. Each of the first drain electrode DE1 and the first source electrode SE1 may include a conductive material including Mo, Al, Cu, Ti, etc., and may have a multi-layer or a single-layer structure including the aforementioned materials. According to one or more embodiments, the first drain electrodes DE1 and the first source electrode SE1 may have a multi-layer structure of Ti/Al/Ti.

The switching thin-film transistor T2 may include a second semiconductor layer Act2, a second gate electrode GE2, a second drain electrode DE2, and a second source electrode SE2. The second semiconductor layer Act2, the second gate electrode GE2, the second drain electrode DE2, and the second source electrode SE2 are respectively similar to the first semiconductor layer Act1, the first gate electrode GE1, the first drain electrode DE1, and the first source electrode SE1, and thus a detailed description thereof will be omitted.

The first organic insulating layer 115 may be located to cover the first drain electrode DE1 and the first source electrode SE1. The first organic insulating layer 115 may include an organic material. For example, the first organic insulating layer 115 may include an organic insulating material, such as a commercial polymer (e.g., polymethyl methacrylate (PMMA) or polystyrene (PS)), a polymer derivative having a phenol-based group, an acrylic polymer, an imide-based polymer, an acryl ether-based polymer, an amide-based polymer, a fluorine-based polymer, a p-xylene-based polymer, a vinyl alcohol-based polymer, and/or a blend thereof.

The second organic insulating layer 116 may include an organic material. The second organic insulating layer 116 may include an organic insulating material, such as a commercial polymer (e.g., PMMA or PS), a polymer derivative having a phenol-based group, an acrylic polymer, an imide-based polymer, an acryl ether-based polymer, an amide-based polymer, a fluorine-based polymer, a p-xylene-based polymer, a vinyl alcohol-based polymer, and/or a blend thereof.

The second pixel circuit PC2 may also include the driving thin-film transistor T1, the switching thin-film transistor T2, and the storage capacitor Cst. Because the above description of the driving thin-film transistor T1, the switching thin-film transistor T2, and the storage capacitor Cst of the first pixel circuit PC1 is equally applicable to the driving thin-film transistor T1, the switching thin-film transistor T2, and the storage capacitor Cst of the second pixel circuit PC2, redundant descriptions thereof will be omitted.

An organic material layer OL, a connection line CWL, and an organic insulating layer OIL may be arranged on the connection area CA of the substrate 100. In detail, the organic material layer OL, the connection line CWL, and the organic insulating layer OIL may be arranged on the first connection area CA1.

The inorganic insulating layer IIL of the pixel circuit layer PCL may be omitted from the connection area CA of the substrate 100. In detail, the inorganic insulating layer IIL of the pixel circuit layer PCL may be omitted from the first connection area CA1. The inorganic insulating layer IIL of the pixel circuit layer PCL may also be omitted from a portion of the first pixel area PA1 adjacent to the first connection area CA1, and from a portion of the second pixel area PA2 adjacent to the first connection area CA1. In other words, the inorganic insulating layer IIL of the pixel circuit layer PCL may be located only on a portion of the first pixel area PA1 that corresponds to the first pixel PX1 and on a portion of the second pixel area PA2 that corresponds to the second pixel PX2. However, the disclosure is not limited thereto, and the inorganic insulating layer IIL of the pixel circuit layer PCL may be located on the entirety of the first pixel area PA1 and the entirety of the second pixel area PA2. In other words, the inorganic insulating layer IIL of the pixel circuit layer PCL may have an approximately cross shape corresponding to the first pixel area PA1 and the second pixel area PA2.

Accordingly, the organic material layer OL may be located on the connection area CA of the substrate 100. In detail, the organic material layer OL may be located on the first connection area CA1. Because the organic material layer OL has lower hardness than an inorganic material, the organic material layer OL absorbs a tensile stress generated due to deformation of the shape of the first connection area CA1, and thus may reduce or minimize concentration of a stress on the connection line CWL located on the organic material layer OL. In addition, as the organic material layer OL is located below the connection line CWL, a neutral plane may be located on the location of the connection line CWL.

A thickness OLt of the organic material layer OL may be substantially the same as a thickness of the inorganic insulating layer IIL formed on the first pixel area PA1 and the second pixel area PA2. As the organic material layer OL having substantially the same thickness as the thickness of the inorganic insulating layer IIL formed on the first pixel area PA1 and the second pixel area PA2 is located on the first connection area CA1, flexibility of the connection area CA may be improved, and an area where the connection line CWL is to be located may be maximally or suitably planarized, thereby leading to an improvement in the reliability of the connection line CWL. In other words, when the connection line CWL, which is located on the organic material layer OL, extends to the first pixel area PA1 and/or the second pixel area PA2, a difference between heights of the connection line CWL and the first pixel area PA1 and/or the second pixel area PA2 may not be generated, or may be reduced or minimized.

The organic material layer OL may include an organic insulating material, such as polyimide, polyamide, acryl resin, benzocyclobutene, hexamethyldisiloxane (HMDSO), or phenol resin. The organic material layer OL may be a single layer or multi-layer including such an organic insulating material.

The connection line CWL may be located on the organic material layer OL. The connection line CWL may be a line that electrically connects the first and second pixel circuits PC1 and PC2 to each other. The connection line CWL may be electrically connected to the first pixel circuit PC1. The first pixel circuit PC1 of the first pixel area PA1 may be electrically connected to a pixel circuit of another pixel area adjacent to the first pixel area PA1 (for example, the second pixel circuit PC2 of the second pixel area PA2) through the connection line CWL. Alternatively, the connection line CWL may be a line that provides various signals and/or voltages to the first and second pixel circuits PC1 and PC2. For example, the connection line CWL may be a line through which various signals and voltages are transmitted, such as a data line, a scan line, or a power supply line.

The connection line CWL may include a highly conductive material. The connection line CWL may include a conductive material including molybdenum (Mo), aluminum (Al), copper (Cu), and/or titanium (Ti), and may be formed as a multi-layer or a single layer including the aforementioned materials. According to one or more embodiments, the connection line CWL may have a multi-layer structure of Ti/Al/Ti. The connection line CWL may include the same material as that included in the first source electrode SE1 or the first drain electrode DE1 of the driving thin-film transistor T1. Alternatively, the connection line CWL may include the same material as that included in the first gate electrode GE1 of the driving thin-film transistor T1. The connection line CWL may include the same material as that included in the second source electrode SE2 or the second drain electrode DE2 of the switching thin-film transistor T2. Alternatively, the connection line CWL may include the same material as that included in the second gate electrode GE2 of the switching thin-film transistor T2.

The connection line CWL may be covered with the organic insulating layer OIL. The organic insulating layer OIL of the pixel circuit layer PCL may be formed to entirely cover the substrate 100. Accordingly, a portion of the organic insulating layer OIL may be located also over (e.g., in) the connection area CA, and the connection line CWL may be covered with a portion of the organic insulating layer OIL located over the connection area CA. In detail, a portion of the organic insulating layer OIL may be located also over the first connection area CA1, and the connection line CWL may be covered with a portion of the organic insulating layer OIL located over the first connection area CA1.

The display element layer DEL may be located on the pixel circuit layer PCL of the pixel area PA. In detail, the pixel circuit layer PCL may be located on the first pixel area PA1 and the second pixel area PA2, and the display element layer DEL may be located on the pixel circuit layer PCL. The display element layer DEL may include display elements. In detail, the first organic light-emitting diode OLED1 may be located as a display element on the first pixel area PA1, and the second organic light-emitting diode OLED2 may be located as a display element on the second pixel area PA2. The first organic light-emitting diode OLED1 may be located on a portion of the pixel circuit layer PCL located on the first pixel area PA1, and the second organic light-emitting diode OLED2 may be located on a portion of the pixel circuit layer PCL located on the second pixel area PA2.

The display element layer DEL may include a passivation layer PVX and a pixel-defining layer 118. The passivation layer PVX may be located on the second organic insulating layer 116 of the pixel area PA. In detail, a portion of the second organic insulating layer 116 may be located over the first pixel area PA1 and the second pixel area PA2, and the passivation layer PVX may be located on the portion of the second organic insulating layer 116. The passivation layer PVX may not be located on another portion of the second organic insulating layer 116 located over the first connection area CA1. The passivation layer PVX may be located between the first organic light-emitting diode OLED1 and the second organic insulating layer 116, and between the second organic light-emitting diode OLED2 and the second organic insulating layer 116. In detail, the passivation layer PVX may be located between a 1-1^{st} electrode 211 and the second organic insulating layer 116, and between a 1-2^{nd} electrode 216 and the second organic insulating layer 116. The passivation layer PVX may be a single layer or a multi-layer including inorganic materials, such as silicon nitride (SiN_{X}) and/or silicon oxide (SiO₂).

The first organic light-emitting diode OLED1 may include the 1-1^{st} electrode 211, a first intermediate layer 212, and a second electrode 213. The 1-1^{st} electrode 211 may be electrically connected to a connection metal CM on the first pixel area PA1 through a contact hole of the second organic insulating layer 116. Accordingly, the first organic light-emitting diode OLED1 may be electrically connected to the first pixel circuit PC1. For example, the 1-1^{st} electrode 211 may be a pixel electrode of the first organic light-emitting diode OLED1, and the second electrode 213 may be an opposite electrode of the first organic light-emitting diode OLED1.

The 1-1^{st} electrode 211 may include conductive oxide, such as indium tin oxide (ITO), indium zinc oxide (IZO), zinc oxide (ZnO), indium oxide (In₂O₃), indium gallium oxide (IGO), and/or aluminum zinc oxide (AZO). According to one or more other embodiments, the 1-1^{st} electrode 211 may include a reflection layer including, for example, silver (Ag), magnesium (Mg), aluminum (Al), platinum (Pt), palladium (Pd), gold (Au), nickel (Ni), neodymium (Nd), iridium (Ir), chromium (Cr), and/or a compound of these materials. According to one or more other embodiments, the 1-1^{st} electrode 211 may further include a layer formed of ITO, IZO, ZnO, and/or In₂O₃ over/under the aforementioned reflection layer.

The pixel-defining layer 118 may be arranged on the 1-1^{st} electrode 211. The pixel-defining layer 118 may be located over the first pixel area PA1 and the second pixel area PA2, and may be omitted from the first connection area CA1. In FIG. 6, the pixel-defining layer 118 is also omitted from a portion of the first pixel area PA1 adjacent to the first connection area CA1 and from a portion of the second pixel area PA2 adjacent to the first connection area CA1. However, the disclosure is not limited thereto.

The pixel-defining layer 118 may include an opening via which an upper surface of the 1-1^{st} electrode 211 is exposed, and may cover an edge(s) of the 1-1^{st} electrode 211. Accordingly, the pixel-defining layer 118 may define a light-emission region of the first pixel PX1. The pixel-defining layer 118 may include an opening via which an upper surface of the 1-2^{nd} electrode 216 is exposed, and may cover an edge(s) of the 1-2^{nd} electrode 216 to thereby define a light-emission region of the second pixel PX2. The pixel-defining layer 118 may include an organic insulating material. Alternatively, the pixel-defining layer 118 may include an inorganic insulating material, such as silicon nitride (SiNx), silicon oxynitride (SiON), or silicon oxide (SiOx). Alternatively, the pixel-defining layer 118 may include an organic insulating material and an inorganic insulating material.

According to one or more embodiments, a spacer may be located on the pixel-defining layer 118. A mask sheet may be used in a method of manufacturing the display apparatus 1. In this case, the mask sheet may enter (e.g., partially) the opening of the pixel-defining layer 118, or may adhere to the pixel-defining layer 118. The spacer may reduce or prevent the likelihood of a defect, such as damage to, or destruction of, the substrate 100, and a multi-layered film on the substrate 100 due to the mask sheet when a deposition material is deposited on the substrate 100.

The spacer may include an organic material, such as polyimide. Alternatively, the spacer may include an inorganic insulating material, such as silicon nitride (SiNx) or silicon oxide (SiO₂), or may include an inorganic insulating material and an organic insulating material.

According to one or more embodiments, the spacer may include a different material as that of the pixel-defining layer 118. According to one or more other embodiments, the spacer may include the same material as that included in the pixel-defining layer 118. In this case, the pixel-defining layer 118 and the spacer may be formed together in a mask process using a halftone mask or the like.

The first intermediate layer 212 may be located on the pixel-defining layer 118. The first intermediate layer 212 may include a first emission layer 212b located in the opening of the pixel-defining layer 118. The first emission layer 212b may include a low-molecular-weight or high-molecular-weight organic material that emits light of a certain color.

A first functional layer 212a and a second functional layer 212c may be located under and over the first emission layer 212b, respectively. The first functional layer 212a may include, for example, a hole transport layer (HTL), or may include an HTL and a hole injection layer (HIL). The second functional layer 212c is a component located over the first emission layer 212b, and is optional. The second functional layer 212c may include an electron transport layer (ETL) and/or an electron injection layer (EIL). The first functional layer 212a and/or the second functional layer 212c may be a common layer that entirely covers the substrate 100, similar to the second electrode 213 to be described later.

The second electrode 213 may include a conductive material having a low work function. For example, the second electrode 213 may include a (semi)transparent layer including, for example, silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca) or an alloy of these materials. Alternatively, the second electrode 213 may further include a layer, such as ITO, IZO, ZnO, and/or In₂O₃, on the (semi)transparent layer including any of the above-described materials. The second electrode 213 may be formed to entirely cover the substrate 100, similar to the first functional layer 212a and/or the second functional layer 212c. The second electrode 213 is located over the pixel area PA. As illustrated in FIG. 6, the second electrode 213 may cover the pixel area PA. In other words, the second electrode 213 may be formed as a single body constituting a plurality of organic light-emitting diodes, and thus may correspond to a plurality of pixel electrodes. The second electrode 213 may be located over the pixel area PA and the connection area CA of the substrate 100. In detail, the second electrode 213 may be located over the first pixel area PA1, the second pixel area PA2, and the first connection area CA1.

The second organic light-emitting diode OLED2 may include the 1-2^{nd} electrode 216, a second intermediate layer 217, and the second electrode 213. The second intermediate layer 217 may include the first functional layer 212a, the second emission layer 217b, and the second functional layer 212c. For example, the 1-2^{nd} electrode 216 may be a pixel electrode of the second organic light-emitting diode OLED2, and the second electrode 213 may be an opposite electrode of the second organic light-emitting diode OLED2. The above descriptions of the 1-1^{st} electrode 211, the first intermediate layer 212, and the first emission layer 212b of the first organic light-emitting diode OLED1 are equally applicable to the 1-2^{nd} electrode 216, the second intermediate layer 217, and the second emission layer 217b of the second organic light-emitting diode OLED2, and thus redundant descriptions thereof will be omitted. As described above, the first functional layer 212a, the second functional layer 212c, and the second electrode 213 are common layers that cover the entirety of the substrate 100, and thus the above descriptions of the first functional layer 212a, the second functional layer 212c, and the second electrode 213 included in the first organic light-emitting diode OLED1 may be equally applied to the first functional layer 212a, the second functional layer 212c, and the second electrode 213 included in the second organic light-emitting diode OLED2. Thus, repeated descriptions thereof will be omitted.

In one or more embodiments, a portion of the passivation layer PVX adjacent to the first connection area CA1 in a plan view may define a passivation hole. In other words, a portion of the passivation layer PVX that is adjacent to the first connection area CA1 in a plan view, and that is located over the first pixel area PA1, may define a passivation hole, and a portion of the passivation layer PVX that is adjacent to the first connection area CA1 in a plan view, and that is located over the second pixel area PA2, may also define a passivation hole. External oxygen or moisture may flow into the first organic light-emitting diode OLED1 and the second organic light-emitting diode OLED2 via at least one of the first functional layer 212a or the second functional layer 212c, and may destroy the first organic light-emitting diode OLED1 and the second organic light-emitting diode OLED2. However, each of the first functional layer 212a and the second functional layer 212c may be disconnected by the passivation hole, and thus infiltration of moisture or oxygen into the first organic light-emitting diode OLED1 and the second organic light-emitting diode OLED2 may be prevented or reduced. Accordingly, the reliability of the display apparatus 1 may be increased.

The display apparatus 1 may further include a capping layer CPL. The capping layer CPL may serve to improve external luminescence efficiency of the organic light-emitting diode OLED according to constructive interference. The capping layer CPL may be located on the second electrode 213 of the pixel area PA. In detail, a portion of the second electrode 213 may be located over the first pixel area PA1 and the second pixel area PA2, and the capping layer CPL may be located on the portion of the second electrode 213. The capping layer CPL may not be located on another portion of the second electrode 213 located over the first connection area CA1.

The capping layer CPL may include an organic insulating material. For example, the capping layer CPL may include at least one of triamine derivatives, carbazole biphenyl derivatives, arylenediamine derivatives, tris-8-hydroxyquinoline aluminum (Alq3), acrylic, polyimide, or polyamide. Alternatively, the capping layer CPL may include an inorganic insulating material, such as silicon nitride.

The first functional layer 212a, the second functional layer 212c, and the second electrode 213 may be located on a portion of the organic insulating layer OIL located over the connection area CA. Because the first functional layer 212a, the second functional layer 212c, and the second electrode 213 are formed to cover the entirety of the substrate 100 as described above, the first functional layer 212a, the second functional layer 212c, and the second electrode 213 may be sequentially stacked on the portion of the organic insulating layer OIL located over the connection area CA. In detail, the first functional layer 212a, the second functional layer 212c, and the second electrode 213 may be sequentially stacked on a portion of the organic insulating layer OIL located over the first connection area CA1.

The display apparatus 1 may further include a pattern layer PL (e.g., a first pattern layer PL1 and a second pattern layer PL2). The pattern layer PL may be located on a portion of the second electrode 213 in the connection area CA. In detail, the pattern layer PL may be located on a portion of the second electrode 213 in the third area A3 of the first connection area CA1. The pattern layer PL may improve the flexibility of the first connection area CA1 by inducing a crack generated in the encapsulation layer 300 in the first connection area CA1 to be instead generated in the encapsulation layer 300 in the third area A3.

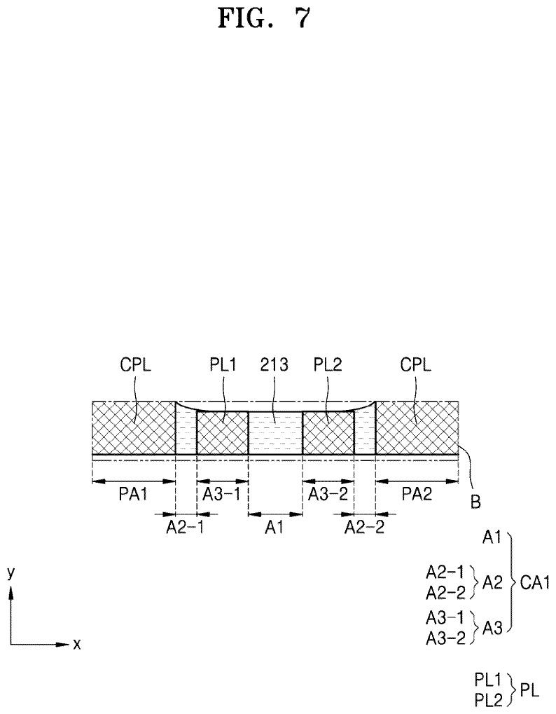

As shown in FIG. 7, which is a schematic plan view of the pattern layer PL of the display apparatus 1, the pattern layer PL may be located over the first connection area CA1 to be biased from the center portion of the first connection area CA1 toward the first pixel area PA1 or the second pixel area PA2 in a plan view. FIG. 7 is a schematic magnified view of a portion B of FIG. 5. However, for convenience of explanation, FIG. 7 shows a plan view on the second electrode 213.

In detail, the pattern layers PL may be located over the third area A3 of the first connection area CA1. The pattern layer PL may include a first pattern layer PL1 and a second pattern layer PL2. The first pattern layer PL1 may be located over the first connection area CA1 to be biased from the center portion of the first connection area CA1 toward the first pixel area PA1 in a plan view, and the second pattern layer PL2 may be located over the first connection area CA1 to be biased from the center portion of the first connection area CA1 toward the second pixel area PA2 in a plan view. In other words, the first pattern layer PL1 may be located over the 3-1^{st} area A3-1, and the second pattern layer PL2 may be located over the 3-2^{nd} area A3-2.

The pattern layer PL may be spaced apart from the capping layer CPL in a plan view. In detail, the first pattern layer PL1 may be located over the 3-1^{st} area A3-1, and the 2-1^{st} area A2-1 may be located between the 3-1^{st} area A3-1 and the first pixel area PA1. Accordingly, in a plan view, the first pattern layer PL1 may be spaced apart from the capping layer CPL located over the first pixel area PA1. The second pattern layer PL2 may be located over the 3-2^{nd} area A3-2, and the 2-2^{nd} area A2-2 may be located between the 3-2^{nd} area A3-2 and the second pixel area PA2. Accordingly, in a plan view, the second pattern layer PL2 may be spaced apart from the capping layer CPL located over the second pixel area PA2.

The pattern layer PL may include the same material as that included in the capping layer CPL located over the first pixel area PA1 and the second pixel area PA2. For example, the pattern layer PL may include an organic insulating material. For example, the pattern layer PL may include at least one of triamine derivatives, carbazole biphenyl derivatives, arylenediamine derivatives, tris-8-hydroxyquinoline aluminum (Alq3), acrylic, polyimide, and/or polyamide. Alternatively, the pattern layer PL may include an inorganic insulating material, such as silicon nitride.

The encapsulation layer 300 may be located on the capping layer CPL located over the pixel area PA. In detail, the capping layer CPL may be located over the first pixel area PA1 and the second pixel area PA2, and the encapsulation layer 300 may be located on the capping layer CPL. The encapsulation layer 300 may be formed to entirely cover the substrate 100. In other words, the encapsulation layer 300 may be located over the pixel area PA and the connection area CA of the substrate 100. In detail, the encapsulation layer 300 may be located over the first pixel area PA1, the second pixel area PA2, and the first connection area CA1.

The encapsulation layer 300 may include at least one inorganic encapsulation layer. In detail, as shown in FIG. 6, the encapsulation layer 300 may include a first inorganic encapsulation layer 310 and a second inorganic encapsulation layer 330 sequentially stacked on each other. In other words, the second inorganic encapsulation layer 330 may be located directly on the first inorganic encapsulation layer 310, and thus the first inorganic encapsulation layer 310 and the second inorganic encapsulation layer 330 may be in direct contact with each other on the first organic light-emitting diode OLED1. In this case, the first inorganic encapsulation layer 310 and the second inorganic encapsulation layer 330 may be also in direct contact with each other on the second organic light-emitting diode OLED2.

Each of the first inorganic encapsulation layer 310 and the second inorganic encapsulation layer 330 may include at least one inorganic material from among aluminum oxide (Al₂O₃), titanium oxide (TiO₂), tantalum oxide (Ta₂O₅), hafnium oxide (HfO₂), zinc oxide (ZnO), silicon oxide (SiO₂), silicon nitride (SiNx), and/or silicon oxynitride (SiON).

However, the disclosure is not limited thereto. For example, in one or more embodiments, the encapsulation layer 300 may further include an organic encapsulation layer between the first and second inorganic encapsulation layers 310 and 330. In this case, the organic encapsulation layer may be located to correspond only to the pixel area PA. The first inorganic encapsulation layer 310 and the second inorganic encapsulation layer 330 may be located over the second electrode 213 to entirely and continuously cover the substrate 100, whereas the organic encapsulation layer may be patterned to correspond only to the pixel area PA. For example, as shown in FIG. 6, in the first pixel area PA1, the second pixel area PA2, and the first connection area CA1, which connects the first and second pixel areas PA1 and PA2 to each other, the organic encapsulation layer may be located only over the first pixel area PA1 and the second pixel area PA2, and may by omitted from the first connection area CA1. Because the organic encapsulation layer has a greater thickness than the first inorganic encapsulation layer 310 and the second inorganic encapsulation layer 330, the organic encapsulation layer may not be located over the first connection area CA1, and thus, the flexibility of the connection area CA may be improved.

The organic encapsulation layer may include a polymer-based material. Examples of the polymer-based material may include an acrylic resin, an epoxy-based resin, polyimide, and/or polyethylene. According to one or more embodiments, the organic encapsulation layer may include acrylate.

As described above, the encapsulation layer 300 may be formed to entirely cover the substrate 100. Accordingly, the encapsulation layer 300 may also be located over the connection area CA. In other words, the encapsulation layer 300 may also be located over the first connection area CA1. In other words, the encapsulation layer 300 may be integrally formed in the first pixel area PA1, the first connection area CA1, and the second pixel area PA2. In other words, the first inorganic encapsulation layer 310 and the second inorganic encapsulation layer 330 may be integrally formed in the first pixel area PA1, the first connection area CA1, and the second pixel area PA2. Thus, a portion of the encapsulation layer 300 located over the first connection area CA1 may cover the pattern layer PL. In other words, a portion of the first inorganic encapsulation layer 310 located over the first connection area CA1 may cover the pattern layer PL.

An adhesive strength between the encapsulation layer 300 and the pattern layer PL may be different from an adhesive strength between the encapsulation layer 300 and the second electrode 213. In other words, an adhesive strength between the first inorganic encapsulation layer 310 and the pattern layer PL may be different from an adhesive strength between the first inorganic encapsulation layer 310 and the second electrode 213. In detail, the adhesive strength between the encapsulation layer 300 and the pattern layer PL may be less than the adhesive strength between the encapsulation layer 300 and the second electrode 213. In other words, the adhesive strength between the first inorganic encapsulation layer 310 and the pattern layer PL may be less than the adhesive strength between the first inorganic encapsulation layer 310 and the second electrode 213.

Alternatively, an adhesive strength between the pattern layer PL and the second electrode 213 may be different from an adhesive strength between the encapsulation layer 300 and the second electrode 213. In other words, the adhesive strength between the pattern layer PL and the second electrode 213 may be different from the adhesive strength between the first inorganic encapsulation layer 310 and the second electrode 213. In detail, the adhesive strength between the pattern layer PL and the second electrode 213 may be less than the adhesive strength between the encapsulation layer 300 and the second electrode 213. In other words, the adhesive strength between the pattern layer PL and the second electrode 213 may be less than the adhesive strength between the first inorganic encapsulation layer 310 and the second electrode 213.

In general, an adhesive strength between layers may vary according to the materials contained in the layers. For example, an adhesive strength between a layer including an inorganic material and a layer including an organic insulating material may be about 1/250^{th} to about 1/500^{th} of an adhesive strength between the layer including an inorganic material and a layer including a conductive material. Alternatively, an adhesive strength between a layer including an organic insulating material and the layer including a conductive material may be about 1/250^{th} to about 1/500^{th} of the adhesive strength between the layer including an inorganic material and the layer including a conductive material. As described above, the first inorganic encapsulation layer 310 may include an inorganic material, the second electrode 213 may include a conductive material, and the pattern layer PL may include an organic insulating material. Accordingly, the adhesive strength between the first inorganic encapsulation layer 310 and the pattern layer PL may be less than the adhesive strength between the first inorganic encapsulation layer 310 and the second electrode 213. Alternatively, the adhesive strength between the pattern layer PL and the second electrode 213 may be less than the adhesive strength between the first inorganic encapsulation layer 310 and the second electrode 213.

As shown in FIGS. 6 and 7, a layer located below a portion of the encapsulation layer 300 in the connection area CA may vary according to locations in the connection area CA. Accordingly, an adhesive strength between the portion of the encapsulation layer 300 in the connection area CA and the layer located below the portion of the encapsulation layer 300 in the connection area CA may vary according to locations in the connection area CA. In detail, an adhesive strength between a portion of the first inorganic encapsulation layer 310 in the first connection area CA and a layer located below the portion of the first inorganic encapsulation layer 310 in the first connection area CA1 may vary according to locations in the first connection area CA1. In other words, an adhesive strength between a portion of the first inorganic encapsulation layer 310 on the first connection area CA1 of the substrate 100 and a layer located below the portion may vary according to locations at the first connection area CA1.

For example, a layer located below a portion of the first inorganic encapsulation layer 310 in the first area A1 may be the second electrode 213, a layer located below a portion of the first inorganic encapsulation layer 310 in the second area A2 may be the second electrode 213, and a layer located below a portion of the first inorganic encapsulation layer 310 in the third area A3 may be the pattern layer PL. An adhesive strength between the portion of the first inorganic encapsulation layer 310 located over the third area A3 and the pattern layer PL may be less than an adhesive strength between the portion of the first inorganic encapsulation layer 310 located over the first area A1 and the second electrode 213. The adhesive strength between the portion of the first inorganic encapsulation layer 310 located over the third area A3 and the pattern layer PL may be less than the adhesive strength between the portion of the first inorganic encapsulation layer 310 located over the second area A2 and the second electrode 213. Thus, the portion of the first inorganic encapsulation layer 310 located over the third area A3 may be more suitably separated from a layer located below the portion. This may induce cracks to occur in the portion of the first inorganic encapsulation layer 310 located over the third area A3. Thus, the pattern layer PL causes a crack of the encapsulation layer 300 located over the connection area CA to occur in a preset portion of the encapsulation layer 300, thereby improving the flexibility of the connection area CA.

As described above with reference to FIG. 2, when the substrate 100 is stretched, stress may be concentrated on a portion of the first connection area CA1 connected to the edge of the first pixel area PA1. This stress concentration may cause, for example, tearing of the first connection area CA1. As described above with reference to FIG. 3, when an external force, such as a compression force is applied to the substrate 100, the first connection area CA1 may be bent, and the center portion of the first connection area CA1 may be moved farthest from the first pixel area PA1 and the second pixel area PA2 in the third direction (for example, the +z direction or the −z direction). In other words, the first area A1 and the second area A2 of the first connection area CA1 may be deformed the most by the external force, and the stress may be concentrated on the first area A1 and the second area A2 of the first connection area CA1.

In the case of the display apparatus 1, the second electrode 213 may be located below the encapsulation layer 300 located over the first area A1 and the second area A2. In other words, the second electrode 213 may be located below the first inorganic encapsulation layer 310 located over the first area A1 and the second area A2. Accordingly, an adhesive strength between a portion of the first inorganic encapsulation layer 310 in the first area A1 and in the second area A2 and a layer located below the portion may be large. Thus, the portion of the first inorganic encapsulation layer 310 in the first area A1 and the second area A2 may not be separated from the layer located below the portion. Accordingly, the position of a preset neutral plane may not be changed, and concentration of stress on the connection line CWL or the like may be reduced or minimized.

In FIGS. 6 and 7, the pattern layer PL completely covers the portion of the second electrode 213 located over the third area A3. However, the disclosure is not limited thereto. For example, the pattern layer PL may partially cover a portion of the second electrode 213 located over the third area A3.

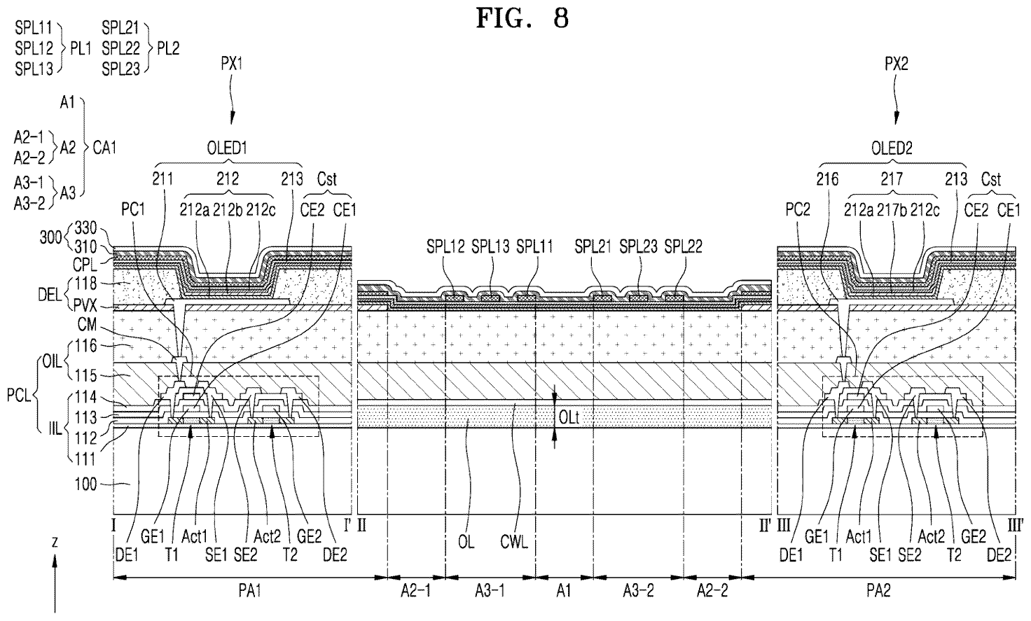

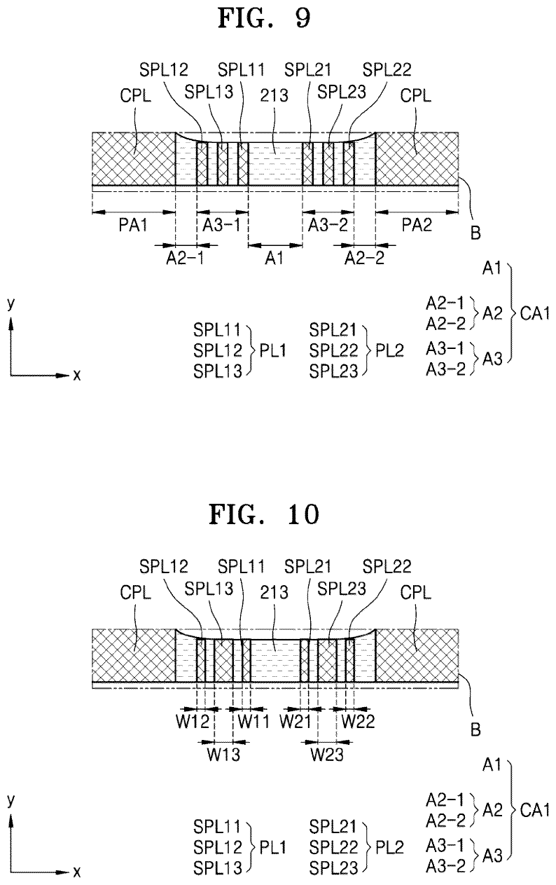

FIG. 8 is a schematic cross-sectional view of a portion of a display apparatus 1 according to one or more embodiments, and FIG. 9 is a schematic plan view of a portion of the display apparatus 1 according to one or more embodiments. For convenience of explanation, FIG. 9 shows a plan view on the second electrode 213. Because the display apparatus 1 is similar to the display apparatus 1 described above with reference to FIGS. 1 through 7, a difference from the display apparatus 1 described above with reference to FIGS. 1 through 7 will now be focused on and described. Reference numerals in FIGS. 8 and 9 that are the same as the reference numerals in FIGS. 1 through 7 denote the same elements, and thus repeated descriptions thereof are omitted.

The pattern layer PL included in the display device 1 described above with reference to FIG. 7 may be located over the third area A3 of the first connection area CA1. The pattern layer PL may also be located over the third area A3 of the first connection area CA1 of the display apparatus 1. However, in the display apparatus 1, the pattern layer PL may partially cover a portion of the second electrode 213 located over the third area A3. In other words, the pattern layer PL may be located only on a portion of the portion of the second electrode 213 located over the third area A3.

In detail, the pattern layer PL may include a plurality of sub-pattern layers. For example, in a plan view, the sub-pattern layers may be spaced apart from each other in the first direction (for example, the +x direction or the −x direction). These sub-pattern layers may extend in the second direction (for example, the +y direction or the −y direction). As described above, the pattern layer PL may include a first pattern layer PL1 located over the 3-1^{st} area A3-1, and may include a second pattern layer PL2 located over the 3-2^{nd} area A3-2. The first pattern layer PL1 may include some of the sub-pattern layers, and the second pattern layer PL2 may include the others of the sub-pattern layers.

In other words, the first pattern layer PL1 may include a plurality of first sub-pattern layers, and the second pattern layer PL2 may include a plurality of second sub-pattern layers. The plurality of first sub-pattern layers may include a 1-1^{st} sub-pattern layer SPL11, a 1-2^{nd} sub-pattern layer SPL12, and a 1-3^{rd} sub-pattern layer SPL13, and the second sub-pattern layers may include a 2-1^{st} sub-pattern layer SPL21, a 2-2^{nd} sub-pattern layer SPL22, and a 2-3^{rd} sub-pattern layer SPL23.

In detail, the first pattern layer PL1 may include the 1-1^{st} sub-pattern layer SPL11, the 1-2^{nd} sub-pattern layer SPL12, and the 1-3^{rd} sub-pattern layer SPL13. In a plan view, the 1-1^{st} sub-pattern layer SPL11 may be located adjacent to the first area A1, the 1-2^{nd} sub-pattern layer SPL12 may be located adjacent to the 2-1^{st} area A2-1, and the 1-3^{rd} sub-pattern layer SPL13 may be located between the 1-1^{st} sub-pattern layer SPL11 and the 1-2^{nd} sub-pattern layer SPL12. The second pattern layer PL2 may include the 2-1^{st} sub-pattern layer SPL21, the 2-2^{nd} sub-pattern layer SPL22, and the 2-3^{rd} sub-pattern layer SPL23. In a plan view, the 2-1^{st} sub-pattern layer SPL21 may be located adjacent to the first area A1, the 2-2^{nd} sub-pattern layer SPL22 may be located adjacent to the 2-2^{nd} area A2-2, and the 2-3^{rd} sub-pattern layer SPL23 may be located between the 2-1^{st} sub-pattern layer SPL21 and the 2-2^{nd} sub-pattern layer SPL22.

The 1-1^{st} sub-pattern layer SPL11, the 1-2^{nd} sub-pattern layer SPL12, and the 1-3^{rd} sub-pattern layer SPL13 may also be located over the 3-1^{st} area A3-1. Further, the 1-1^{st} sub-pattern layer SPL11, the 1-2^{nd} sub-pattern layer SPL12, and the 1-3^{rd} sub-pattern layer SPL13 may be spaced apart from each other in the first direction (for example, the +x direction or the −x direction). The 1-1^{st} sub-pattern layer SPL11, the 1-2^{nd} sub-pattern layer SPL12, and the 1-3^{rd} sub-pattern layer SPL13 may extend in the second direction (for example, the +y direction or the −y direction).

The 2-1^{st} sub-pattern layer SPL21, the 2-2^{nd} sub-pattern layer SPL22, and the 2-3^{rd} sub-pattern layer SPL23 may also be located over the 3-2^{nd} area A3-2, and the 2-1^{st} sub-pattern layer SPL21, the 2-2^{nd} sub-pattern layer SPL22, and the 2-3^{rd} sub-pattern layer SPL23 may be spaced apart from each other in the first direction (for example, the +x direction or the −x direction). The 2-1^{st} sub-pattern layer SPL21, the 2-2^{nd} sub-pattern layer SPL22, and the 2-3^{rd} sub-pattern layer SPL23 may extend in the second direction (for example, the +y direction or the −y direction).

Although the widths of the first sub-pattern layers are the same in FIGS. 8 and 9, the disclosure is not limited thereto. For example, the widths of the first sub-pattern layers may be different from each other. A width of a sub-pattern layer used herein refers to a length in the first direction (for example, the +x direction or the −x direction).

In detail, as shown in FIG. 10, which is a schematic plan view of a portion of the display apparatus 1 according to one or more embodiments, the 1-1^{st} sub-pattern layer SPL11 may have a 1-1^{st} width W11, the 1-2^{nd} sub-pattern layer SPL12 may have a 1-2^{nd} width W12, and the 1-3^{rd} sub-pattern layer SPL13 may have a 1-3^{rd} width W13. The 1-2^{nd} width W12 may be equal to or similar to the 1-1^{st} width W11, and the 1-3^{rd} width W13 may be greater than the 1-1^{st} width W11. Alternatively, the 1-3^{rd} width W13 may be greater than the 1-1^{st} width W11, and the 1-2^{nd} width W12 may be greater than the 1-3^{rd} width W13. In other words, a width of a first sub-pattern layer more adjacent to the first area A1 in a plan view may be less than that of a first sub-pattern layer less adjacent to the first area A1 in a plan view. The above-descriptions of the first pattern layer PL1 and the first sub-pattern layers are equally applicable to the second pattern layer PL2 and the second sub-pattern layers, and thus redundant descriptions thereof will be omitted.

In detail, widths of the second sub-pattern layers are the same in FIGS. 8 and 9, but the widths of the second sub-pattern layers may be different from each other. The 2-1^{st} sub-pattern layer SPL21 may have a 2-1^{st} width W21, the 2-2^{nd} sub-pattern layer SPL22 may have a 2-2^{nd} width W22, and the 2-3^{rd} sub-pattern layer SPL23 may have a 2-3^{rd} width W23. The 2-2^{nd} width W22 may be equal to or similar to the 2-1^{st} width W21, and the 2-3^{rd} width W23 may be greater than the 2-1^{st} width W21. Alternatively, the 2-3^{rd} width W23 may be greater than the 2-1^{st} width W21, and the 2-2^{nd} width W22 may be greater than the 2-3^{rd} width W23. In other words, a width of a second sub-pattern layer more adjacent to the first area A1 in a plan view may be less than that of a second sub-pattern layer less adjacent to the first area A1 in a plan view. However, the disclosure is not limited thereto.

In FIGS. 9 and 10, the first pattern layer PL1 includes three first sub-pattern layers, and the second pattern layer PL2 includes three second sub-pattern layers. However, the disclosure is not limited thereto. Although the first sub-pattern layers and the second sub-pattern layers have rectangular shapes in FIGS. 9 and 10, the disclosure is not limited thereto. For example, the first sub-pattern layers and the second sub-pattern layers may have triangular or circular shapes.

Even in this case, the portion of the first inorganic encapsulation layer 310 located over the third area A3 may be more suitably separated from a layer located below the portion. Because the pattern layer PL includes a plurality of the sub-pattern layers as described above, the above description of the encapsulation layer 300 and the pattern layer PL is equally applicable to an adhesive strength between the encapsulation layer 300 and the sub-pattern layers. Thus, repeated descriptions thereof will be omitted.

In detail, the adhesive strength between the encapsulation layer 300 and the sub-pattern layers may be different from that between the encapsulation layer 300 and the second electrode 213. For example, the adhesive strength between the encapsulation layer 300 and the sub-pattern layers may be less than that between the encapsulation layer 300 and the second electrode 213. This may induce cracks to occur in the portion of the first inorganic encapsulation layer 310 located over the third area A3. Thus, the sub-pattern layers cause a crack of the encapsulation layer 300 located over the connection area CA to occur in a preset portion of the encapsulation layer 300, thereby improving the flexibility of the connection area CA.

According to one or more embodiments as described above, a display apparatus having increased flexibility may be realized. Of course, the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display apparatus comprising:
a substrate comprising a first pixel area and a second pixel area spaced from each other, and a first connection area between the first pixel area and the second pixel area;
a 1-1^{st} electrode in the first pixel area;
a 1-2^{nd} electrode in the second pixel area;
a second electrode above the 1-1^{st} electrode and the 1-2^{nd} electrode, and extending in the first pixel area, the second pixel area, and the first connection area;
a pattern layer above the second electrode in the first connection area, and biased from a center portion of the first connection area toward the first pixel area or the second pixel area, in plan view; and
an encapsulation layer covering the pattern layer, and extending in the first pixel area, the second pixel area, and the first connection area.

2. The display apparatus of claim 1, further comprising a capping layer in the first pixel area and the second pixel area.

3. The display apparatus of claim 2, wherein the pattern layer is spaced from the capping layer in plan view.

4. The display apparatus of claim 2, wherein the capping layer is above a portion of the second electrode in the first pixel area and the second pixel area, and
wherein the pattern layer is above another portion of the second electrode in the first connection area.

5. The display apparatus of claim 2, wherein the pattern layer comprises a same material as the capping layer.

6. The display apparatus of claim 1, wherein the first connection area comprises a first area comprising the center portion, a second area contacting the first pixel area or the second pixel area, and a third area between the first area and the second area, and
wherein the pattern layer is in the third area.

7. The display apparatus of claim 6, wherein the second area comprises a 2-1^{st} area contacting the first pixel area, and a 2-2^{nd} area contacting the second pixel area,
wherein the third area comprises a 3-1^{st} area between the first area and the 2-1^{st} area, and a 3-2^{nd} area between the first area and the 2-2^{nd} area, and
wherein the pattern layer comprises a first pattern layer in the 3-1^{st} area, and a second pattern layer in the 3-2^{nd} area.

8. The display apparatus of claim 1, wherein an adhesive strength between the encapsulation layer and the pattern layer is different from an adhesive strength between the encapsulation layer and the second electrode.

9. The display apparatus of claim 8, wherein the adhesive strength between the encapsulation layer and the pattern layer is less than the adhesive strength between the encapsulation layer and the second electrode.

10. The display apparatus of claim 1, further comprising:
a first intermediate layer between the 1-1^{st} electrode and the second electrode; and
a second intermediate layer between the 1-2^{nd} electrode and the second electrode.

11. A display apparatus comprising:
a substrate comprising a first pixel area and a second pixel area spaced from each other in a first direction, and a first connection area extending in the first direction between the first pixel area and the second pixel area;
a 1-1^{st} electrode in the first pixel area;
a 1-2^{nd} electrode in the second pixel area;
a second electrode above the 1-1^{st} electrode and the 1-2^{nd} electrode, and extending in the first pixel area, the second pixel area, and the first connection area;
sub-pattern layers spaced from each other in the first direction above the second electrode in the first connection area, biased from a center portion of the first connection area toward the first pixel area or the second pixel area in plan view, and extending in a second direction crossing the first direction; and
an encapsulation layer covering the sub-pattern layers, and extending in the first pixel area, the second pixel area, and the first connection area.

12. The display apparatus of claim 11, further comprising a capping layer in the first pixel area and the second pixel area.

13. The display apparatus of claim 12, wherein the sub-pattern layers are spaced from the capping layer in plan view.

14. The display apparatus of claim 12, wherein the capping layer is above a portion of the second electrode in the first pixel area and the second pixel area, and
wherein the sub-pattern layers are above another portion of the second electrode in the first connection area.

15. The display apparatus of claim 1, wherein the sub-pattern layers comprise a same material as the capping layer.

16. The display apparatus of claim 11, wherein the first connection area comprises a first area comprising the center portion, a second area contacting the first pixel area or the second pixel area, and a third area between the first area and the second area, and
wherein the sub-pattern layers are in the third area.

17. The display apparatus of claim 16, wherein the second area comprises a 2-1^{st} area contacting the first pixel area, and a 2-2^{nd} area contacting the second pixel area,
wherein the third area comprises a 3-1^{st} area between the first area and the 2-1^{st} area, and a 3-2^{nd} area between the first area and the 2-2^{nd} area, and
wherein some of the sub-pattern layers are in the 3-1^{st} area, and others of the sub-pattern layers are in the 3-2^{nd} area.

18. The display apparatus of claim 11, wherein an adhesive strength between the encapsulation layer and the sub-pattern layers is different from an adhesive strength between the encapsulation layer and the second electrode.

19. The display apparatus of claim 18, wherein the adhesive strength between the encapsulation layer and the sub-pattern layers is less than the adhesive strength between the encapsulation layer and the second electrode.

20. The display apparatus of claim 11, further comprising:
a first intermediate layer between the 1-1^{st} electrode and the second electrode; and
a second intermediate layer between the 1-2^{nd} electrode and the second electrode.
